(19) United States
(12) Patent Application Publication
(10) Pub. No.: US 2025/0386458 A1
(43) Pub. Date: Dec. 18, 2025

(54) ELECTRONICS COOLING SYSTEM

(71) Applicant: Raytheon Company, Tewksbury, MA (US)

(72) Inventors: Dennis W. Mercier, Hudson, MA (US); Erin K. Nolan, Montgomery Center, VT (US); Kimberly R. Saviers, Glastonbury, CT (US); Travis L. Mayberry, Dallas, TX (US)

(21) Appl. No.: 18/741,469

(22) Filed: Jun. 12, 2024

(51) Int. Cl. H05K 7/20

(52) U.S. Cl. CPC H05K 7/2039; H05K 7/20318; H05K 7/20336

(57) ABSTRACT

An electronics cooling system including an electronics magazine. The electronics magazine includes a magazine body, one or more capsule sockets, one or more interface shorings positioned within the magazine body relative to the one or more capsule sockets and a magazine heat conductive interface positioned within the magazine body relative to at least one of the one or more capsule sockets. The cooling system includes one or more electronics capsules having a capsule housing, the one or more electronics capsules includes an electronics unit within the capsule housing and a capsule cooling system. The capsule cooling system includes a capsule heat conductive interface in communication with the electronics unit.

### BACKGROUND

Electronics cooling systems are used for maintaining the operating temperature of electronic devices and components since electronic devices and components generate heat during operation. Effective cooling assists in reliability, performance, and longevity of the heat-generating electronic equipment. In some electronics systems, cooling systems include cooling cabinets or cooling housings to assist in reducing the heat emitted form the heat-generating electronic equipment.

In some examples, cooling systems include heat sinks, airflow management, fans, thermal interface materials, liquid cooling systems, heat pipes, cooling cabinets, phase change materials, chillers or air conditioners, and environmental conditions. The listed cooling systems can operate individually as a system, or in combination with several systems. In examples there are passive cooling systems and active cooling systems.

An example of a passive cooling system includes heat sinks. Heat sinks are a cooling solution formed from metals with high thermal conductivity and include fins, pins or other protrusions that assist in increasing the surface area available for heat dissipation. Another passive cooling system includes thermal interface materials. Thermal interface materials are used to improve the heat transfer between the heat-generating electronic component and the heat sink. These materials fill microscopic gaps that can trap air (a poor conductor of heat), thereby reducing thermal resistance. Another passive cooling system includes phase change materials (PCM). PCMs absorb heat by changing state (from solid to liquid or vice versa) at a specific temperature. PCMs are used in some cooling systems to absorb excess heat during peak loads, which helps to stabilize the temperature within electronic enclosures.

An example of an active cooling system includes fans and airflow management systems. These systems include the use of fans to enhance air circulation around electronic components. This helps to carry away the heat more efficiently than passive cooling alone. Proper airflow management within enclosures also assists in reducing hot spots and to, for example, assist in substantially even cooling distribution. Another active cooling system includes liquid cooling systems. Liquid cooling systems use a coolant fluid to transfer heat away from components. This method is used in, for example, high-performance computing and servers. The coolant absorbs heat from the components before being cycled through a radiator to dissipate the heat. Another example of a cooling system includes heat pipes. Heat pipes are vacuum-sealed tubes containing a small amount of liquid under low pressure. As the component heats up, the liquid inside the heat pipe vaporizes and travels to a cooler area of the pipe where it condenses, releasing its latent heat. This cycle transfers heat from hot components to cooler areas.

Some systems include multiple electronic systems that, for example, jointly operate or, for efficiency are housed together. In examples with multiple electronic systems, cooling cabinets, or racks, are used to house multiple electronic components in a confined space. Cooling cabinets are designed to manage a large amount of heat by integrating several cooling technologies, including fans, air conditioners, or liquid cooling systems. The design of cooling cabinets often includes features for efficient airflow management, such as strategic vent placement and sealed cable pass-throughs to prevent air leakage.

### SUMMARY

Managing heat generated during operation of electrical systems assists in maintaining the efficiency, reliability, and longevity of electrical systems. Techniques such as heat sinks, cooling fans, thermal interface materials, and proper ventilation are used to dissipate heat effectively and keep systems operating within safe temperature limits. In some examples, electrical systems generate heat as a natural byproduct of their operation due to several physical processes and inefficiencies. For example, when an electrical current flows through a conductor, such as wires, resistors or other components that have a resistance, energy is lost from the system in the form of heat. In other examples, heat is generated in electrical systems that involve switching from AC to DC or DC to AC, with inverters or with pulse-width modulated controls.

In some examples, electronics are housed in small spaces, such as in locations where packing space is confined or limited. As electronic devices become more powerful and compact, the density of heat generation increases. Electronic systems that operate in confined or limited packaging spaces can also be cooled without being removed from the operation location. For instance, electronic systems retained in a cooling cabinet utilize the cooling systems of the cooling cabinet to reduce the temperature of the electronic systems.

In some examples, an electronics cooling assembly includes an electronics magazine, one or more electronics capsules, and an interface shoring. The electronics magazine includes, for example, a magazine body, one or more capsule sockets a magazine cooling system enveloping the one or more capsule sockets and a magazine heat conductive interface associated with each of the one or more capsule sockets. The each of the one or more electronics capsules includes, for example, a capsule body configured for reception within at least one of the one or more capsule sockets, an electronics unit within the capsule body; a capsule cooling system isolated from the magazine cooling system, and a capsule heat conductive interface in communication with the electronics unit. The one or more interface shoring is coupled with one or more of the electronics magazines or the one or more electronics capsules. The one or more interface shorings are configured to drive the magazine heat conductive interface and capsule heat conductive interface into intimate heat conductive engagement with the capsule body received within the at least one capsule socket of the one or more capsule sockets.

This summary is an overview of some of the teachings of the present application and is not intended to be an exclusive or exhaustive treatment of the present subject matter. Further details are found in the detailed description and appended claims. Other aspects will be apparent to persons skilled in the art upon reading and understanding the following detailed description and viewing the drawings that form a part thereof, each of which is not to be taken in a limiting sense. The scope of the present invention is defined by the appended claims and their legal equivalents.

### BRIEF DESCRIPTION OF THE DRAWINGS

FIG. 1 illustrates an electronics cooling system according to at least one example of the present disclosure.

FIG. 2 illustrates a perspective view a cooling magazine according to at least one example of the present disclosure.

FIGS. 3A and 3B illustrates close-up views of the interface shoring according to at least one example of the present disclosure.

FIG. 4 illustrates a cross section of an electronics cooling system according to at least one example of the present disclosure.

FIG. 5A illustrates a perspective view an electronics capsule according to at least one example of the present disclosure.

FIG. 5B illustrates a close-up view of a portion of an electronics capsule according to at least one example of the present disclosure.

FIG. 6 illustrates a method of cooling an electronics system according to at least one example of the present disclosure.

### DETAILED DESCRIPTION

Electronics systems are, at times, contained within a capsule, container, receptacle, housing or the like. For example, the capsule (e.g., containers, receptacles, housings or the like) includes electronics that, when in operation, generate heat as a byproduct. The capsule including the electronics systems are at times used in conjunction with other capsules including electronics systems. Optionally, the capsules are each retained (e.g., held, housed, positioned) within the same storage system, such as an electronics cabinet or magazine.

In examples, the capsules each generate heat as a result of the operation of the electronics contained within. Since each of the one or more capsules generate heat, the overall heat of the electronics system can accumulate and can potentially damage the electronics included in one or more of the capsules.

Cooling systems are used, for example, to reduce or maintain the temperature of the electronics system. In an example, the cooling system is included in the magazine that retains the one or more capsules. The cooling system can include one or more methods of cooling the electronics system. For example, the cooling system includes fans, air conditioners, or liquid cooling systems. Other examples of the cooling system include heat sinks or other components or environments that assist in reducing the temperature from the elevated temperature generated by the electronics system.

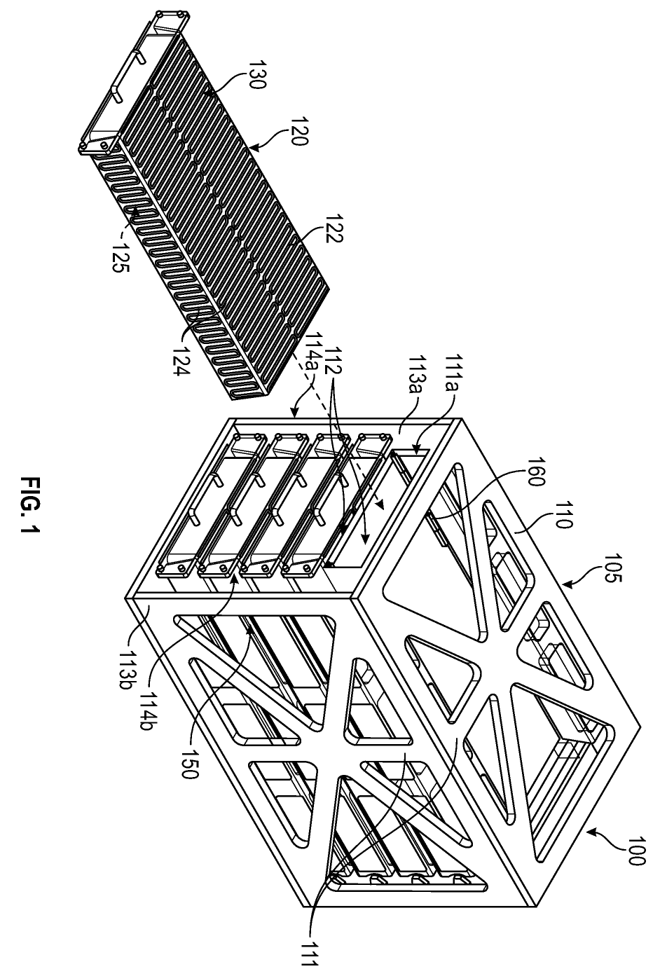

Illustrated in FIG. 1 is an example of an electronics cooling system 100. The electronics cooling system 100 includes, for example an electronics magazine 105 that is formed to retain (e.g., house, contain, support) one or more electronics capsules 120. The electronics cooling system 100 is optionally used in high-power density electronic modules. A high-power density system outputs large amounts of energy relative to its volume. For example, the magazine body 110 includes one or more electronics capsules 120 where each of the one or more electronics capsules 120 are a component of a high-power density electronic module. In examples, the electronics cooling system 100 is used in systems such as radars, computing or other systems where space for components is minimal (relative to other systems that can be housed within a room, building or the like). In other examples the electronics cooling system includes one or more of a radar module, a server module, an avionics module or a control module.

The magazine body 110 includes a structure having, for example, one or more walls 111. The one or more walls 111 defines, for example, the perimeter or the outer support structure of the magazine body 110. The one or more walls 111 are positioned relative to each other to form, for instance, as support structure that restricts movement of the one or more electronics capsules 120 retained within the magazine body 110. The one or more walls 111 of the magazine body 110 are, for example, arranged with an open side 111a. The open side 111a of the magazine body 110 is formed to receive one or more electronics capsules 120.

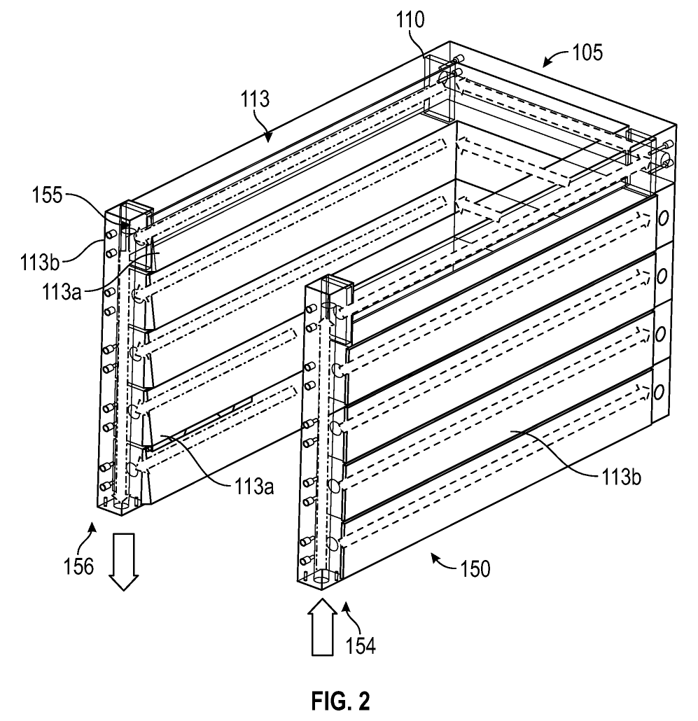

In another example, the magazine body 110 includes one or more walls 111 as accommodating walls. The accommodating walls are optionally hollow structures or spaced walls having a void between an inner wall 113a and an outer wall 113b. The accommodating walls, as discussed further related to FIG. 2, house, contain or retain, for example, a cooling system 150. The cooling system 150 is an example of an external cooling system that assists in reducing the heat from the overall system. The cooling system 150 is an example of a magazine cooling system.

The magazine body 110 includes one or more capsule sockets 112. In some examples, the one or more capsule sockets 112 are shelves that can receive at least one of the one or more electronics capsules 120. The one or more capsule sockets 112 are, for example, sized and shaped to receive one of the one or more electronics capsules 120. For example, the one or more capsule sockets 112, such as a shelf, supports the electronics capsule 120 after the electronics capsule 120 is received or positioned within. In an example, the one or more capsule sockets 112 are stacked or positioned one above the other (or below the other). A magazine body 110 that has one or more capsule sockets 112 can, for example, retain (e.g., house, contain, support) one or more electronics capsules 120. In an example, the one or more electronics capsules 120 retained in the stacked one or more capsule sockets 112 are positioned adjacent (e.g., above or below, or next to) another of the one or more electronics capsules 120.

In the example illustrated in FIG. 1, the one or more electronics capsules 120 is positioned outside of the magazine body 110 in a non-engaged configuration. In an engaged configuration, the one or more electronics capsules 120 is inserted or received within the one or more capsule sockets 112. The one or more electronics capsules 120 includes a capsule body 122. The capsule body 122 is configured for reception, or to be received within at least one of the one or more capsule sockets 112. In other words, the capsule body 122 has a complementary shape to the one or more capsule sockets 112.

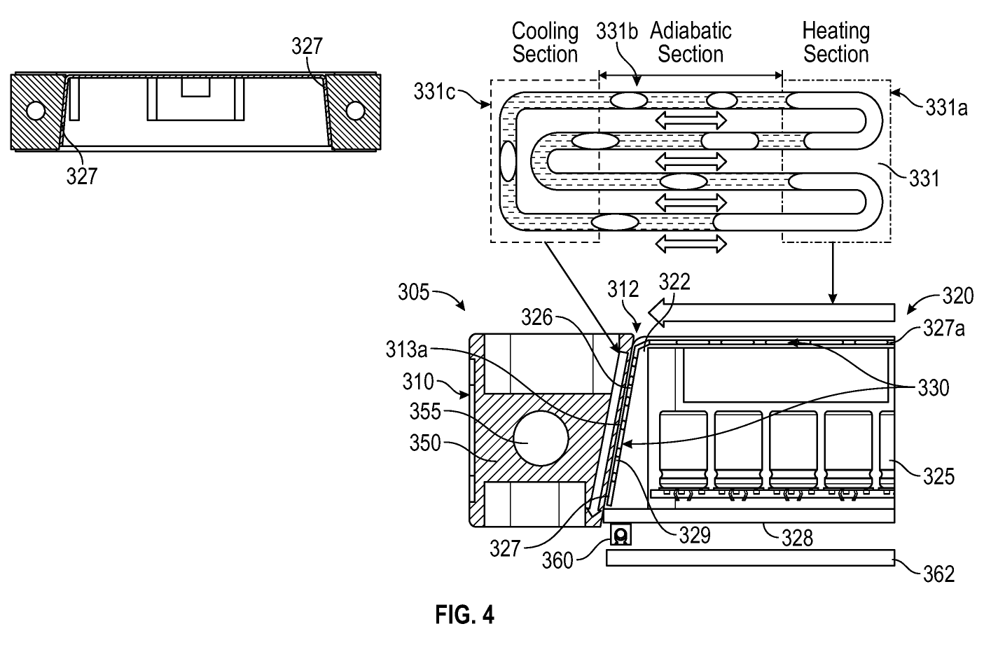

The capsule body 122 includes one or more capsule surfaces 124. In an example, the one or more capsule surfaces 124 is a surface that contacts at least one of the one or more walls 111 of the magazine body 110. For example, and as illustrated in more detail as related to FIG. 4, the one or more capsule surfaces 124 has a complementary profile to be positioned in intimate contact with the one or more walls 111.

In an example, the capsule body 122 houses an electronics unit 125. The electronics unit 125 includes, for example, electrical components such as transistors, resistors, capacitors, computer circuitry or other electrical systems as dictated by the purpose. The electronics unit 125 housed within the capsule body 122 generates heat when in operation. For example, when an electrical current flows through a conductor, such as wires, resistors or other components that have a resistance, energy is lost from the system in the form of heat. The heat generated, in some examples, can damage or degrade individual electrical components or the electronics unit 125.

In an example, to reduce the effect of the heat generated, the one or more electronics capsules 120 includes a capsule cooling system 130. The capsule cooling system 130, for example, is positioned on the capsule body 122. In another example, the capsule cooling system 130 is housed within the one or more capsule surfaces 124. The capsule cooling system 130, for example, is positioned on, or proximate to, a complementary one or more capsule surfaces 124.

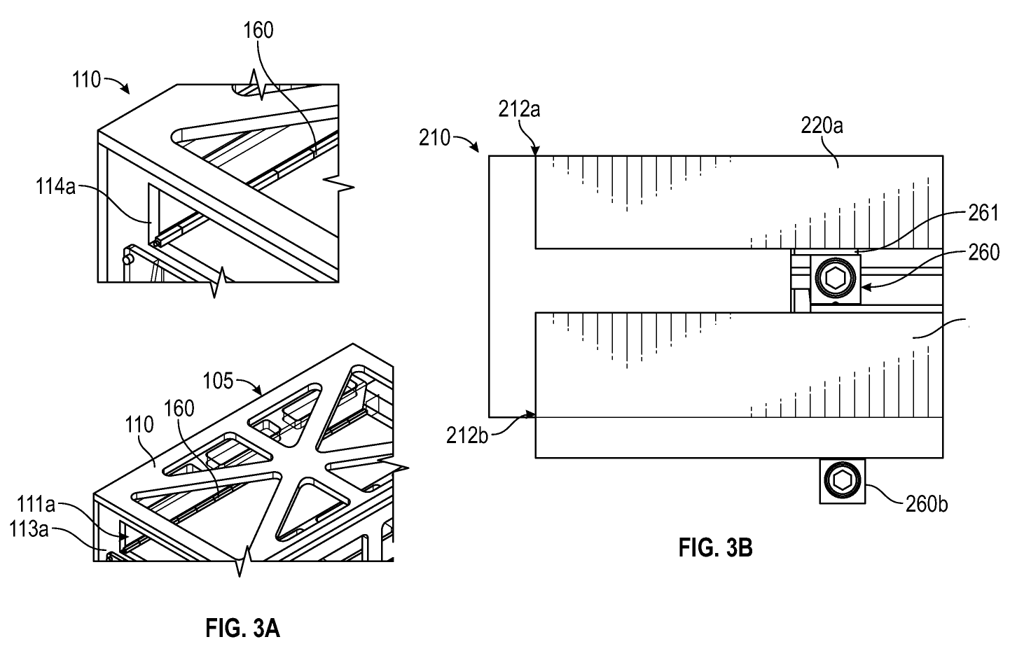

The electronics cooling system 100 includes, for example, one or more interface shorings 160 positioned within the electronics magazine 105. In another example, the one or more interface shorings 160 is positioned on or the one or more electronics capsules 120. As illustrated in the example electronics cooling system 100 in FIG. 1, the one or more interface shorings 160 is positioned proximate to the one or more capsule sockets 112, and as discussed in further detail related to FIGS. 3A and 3B. The one or more interface shorings 160 is positioned relative to the magazine body 110 or the one or more electronics capsules 120 to bring the one or more electronics capsules 120 into intimate contact with the magazine body 110.

Illustrated in FIG. 2 is an example of electronics magazine 105 containing the magazine cooling system 150. The magazine cooling system 150 is, for example, positioned within the magazine body 110. For instance, the cooling system 150 is housed within one or more accommodating walls 113, such as between inner wall 113a and outer wall 113b. In an example, the cooling system 150 is positioned relative to the one or more capsule sockets 112. For instance, the cooling system 150 includes one or more coolant passageways 155 that partially envelopes, envelopes or is positioned on at least one side of the magazine body 110.

The magazine cooling system 150 is, for example, a passive heat exchanger that transfers heat to a fluid. The fluid includes, for example, liquid, gas, a two-phase mixture of liquid and gas, or the like. The fluid, for example, dissipates the heat away from the source of the heat. For instance, the one or more coolant passageways 155 extends within the magazine body 110 to allow for the fluid to be transported from a fluid inlet 154 to a fluid outlet 156 (e.g., fluid return). Optionally, each of the one or more coolant passageways 155 is a separate pathway positioned relative to an associated capsule socket (as illustrated in FIG. 1) that extends at least partially around, or at least partially envelopes, the magazine body 110.

In other examples, the magazine cooling system 150 includes a system with the fluid as air or a gas. For example, the air flows through the coolant passageways 155 to pull or draw heat out of the electronics capsule 120.

In the example of FIG. 2, the cooling system 150 interacts with the one or more electronics capsules 120 (illustrated in FIG. 1). The cooling system 150, for example, includes one or more coolant passageways 155 that is associated with a one or more electronics capsules 120. For example, each of the one or more coolant passageways 155 is cooperatively positioned with the one or more capsule sockets 112 that receives a one or more electronics capsules 120.

Illustrated in FIGS. 3A and 3B are examples of the one or more interface shorings 160. The one or more interface shorings 160 is, for example, positioned within the magazine body 110. The one or more interface shorings 160 is formed to drive the one or more electronics capsules 120 into contact with the magazine body 110. For example, the one or more interface shorings 160 biases the one or more electronics capsules 120 from a position where the one or more capsule surfaces 124 are spaced from the one or more walls 111 of the magazine body 110 to a position where the one or more capsule surfaces 124 are in contact with the one or more walls 111.

In an example the one or more interface shorings 160 is a cam, spring, wedgelock, lift, drive or the like. The one or more interface shorings 160 is, for example, a device that positions, either actively or passively, and supports the one or more electronics capsules 120 relative to the magazine body 110. In another example, the one or more interface shorings 160 includes a biasing member that uses tension to bring two surfaces into a mating relationship.

The more than one interface shorings 160 are optionally positioned within the one or more capsule sockets 112. For example, one or more interface shorings 160 are positioned proximate to one lateral side 114a of the one or more capsule sockets 112 and one or more interface shorings 160 are positioned proximate to a second lateral side 114b (as illustrated in FIG. 1) of the one or more capsule sockets 112. Optionally, the one or more interface shorings 160 is positioned at one or more intermediate positions between the one lateral side 114a and the second lateral side 114b.

Illustrated in FIG. 3B is a close-up view of the one or more interface shorings 160 positioned between a first electronics capsule 220a and a second electronics capsule 220b. The first electronics capsule 220a is positioned, for example, above the second electronics capsule 220b with an interface shoring 260 positioned between. In the example illustrated in FIG. 3B, there is a space 261 between the interface shoring 260 and the first electronics capsule 220a. This is an example of the first electronics capsule 220a in a pre-engaged configuration, such as during installation of the first electronics capsule 220a into a first capsule socket 212a. In the pre-engaged configuration, the interface shoring 260 is not engaged, with the first electronics capsule 220a and the surfaces of the first electronics capsule 220a are positioned away from the first capsule socket 212a.

The second electronics capsule 220b is illustrated in an example of an engaged configuration. In the engaged configuration, the interference interface shoring 260 is, for example, in contact with the second electronics capsule 220b to drive (e.g., urge, bias, lift) the second electronics capsule 220b into contact with at least a portion of the second capsule socket 212b. For example, in the engaged configuration the interface shoring 260b positions and supports the second electronics capsule 220b in contact with at least a portion of the magazine body 210.

In some examples, the interface shoring 260b is mechanically tightened to lift or bring the interface shoring 260b into contact or engagement with the second electronics capsule 220b. In some examples, such as a wedgelock the wedgelock transitions from a pre-engagement configuration to an engagement configuration by rotating at least a portion of the wedgelock. When the interface shoring 260b is brought into engagement with the second electronics capsule 220b, the surfaces of the second electronics capsule 220b are in contact, such as intimate contact with the magazine body 210.

Illustrated in FIG. 4 is an example of an electronics cooling assembly with an electronic capsule 320 in engagement with an electronics magazine 305. Illustrated in FIG. 4 is a cross section of a portion of an electronics capsule 320. The electronics capsule 320 includes a capsule cooling system 330. The capsule cooling system 330 is, for example, a component of the capsule body 322. The capsule body 322 also includes, for example, an electronics unit 325 and a capsule heat conductive interface 326. In other examples, the capsule cooling system 330 is positioned within one or more walls 327 of the capsule body 322. In an example, the one or more walls 327 includes the capsule heat conductive interface 326 as an outer wall that faces an inner wall 313a of a magazine body 310 and an inner wall 329 that faces the electronics unit 325. For instance, the capsule cooling system 330 is positioned proximate to laterally opposed side walls 327 of the capsule body 322. In other examples, the capsule heat conductive interface 326 is positioned in the one or more walls 327 and a top wall 327a.

The capsule heat conductive interface 326 is, for example, in communication with the electronics unit 325. In an example, the capsule heat conductive interface 326 is a tapered surface. Optionally the inner wall 313a, as the magazine heat conductive interface, is reciprocally formed to receive the capsule heat conductive interface 326. For example, the capsule cooling system 330 is positioned relative to the electronics unit 325 to assist in reducing the heat or regulating the temperature of the electronics capsule 320. The electronics unit 325, in some examples, generates heat as a byproduct of its operation. In examples, the heat generated can damage, degrade or cause malfunctioning of the electronics unit 325. When heat is generated, the system benefits from removal or reduction of heat within the system. The capsule cooling system 330, for example, positioned proximate to the capsule heat conductive interface 326 assists in removing or reducing heat generated from the electronics unit 325. In another example, the capsule cooling system 330 is sandwiched, or positioned between, the one or more walls 327 and the inner wall 329.

In one example, the capsule cooling system 330 includes a heat pipe 331. The heat pipe 331 includes a closed system that contains a fluid. In an example operation of the heat pipe 331, the temperature of the liquid contained within the heat pipe increases when heat is dissipated from the electronics unit 325 towards, for example the heating section 331a of the heat pipe 331. The liquid contained within the heat pipe 331, when increasing in temperature can eventually evaporate, producing vapor, for example in an adiabatic section 331b of the heat pipe.

An example of a heat pipe 331 is an oscillating heat pipe. An oscillating heat pipe is also known as a pulsating heat pipe. The heat pipe 331 of an oscillating heat pipe is partially filled with liquid working fluid. The heat pipe 331 in an oscillating heat pipe is arranged in a serpentine pattern in which freely moving liquid and vapor segments alternate. In an oscillating heat pipe, oscillation takes place in the working fluid while the pipe remains motionless. The heat pipe 331, as an oscillation heat pipe, is, for example, positioned proximate to the capsule heat conductive interface 326. In an example, the heat pipe 331 is positioned within or relative to one or more of the top wall 327a or one or more walls 327. The heat pipe 331 for example, carries fluid from proximate to a central portion of the one or more walls 327 or top wall 327a towards more external portions of the respective top wall 327a or one or more walls 327. The heat pipe 331 is positioned in the electronics capsule 320 as an independent, or isolated, cooling system from the magazine cooling system 350 used in the electronics magazine 305. For example, the capsule cooling system 330 is isolated from the magazine cooling system 350.

In an example, the capsule cooling system 330 including a heat pipe 331 is brought into contact with inner wall 313a of the magazine body 310. For instance, the capsule heat conductive interface 326 is an outer wall of the capsule body 322 interposed between the heat pipe 331 and the inner wall 313a. The capsule heat conductive interface 326 when in contact, or engagement, with the inner wall 313a assists in heat removal or reduction when the electronics unit 325 is in operation, or benefits from a reduction of temperature. For example, the capsule heat conductive interface 326 cooperatively operates with the magazine heat conductive interface, as the inner wall 313a.

The inner wall 313a is an example of a magazine heat conductive interface. In an example, the electronics magazine 305 includes a magazine cooling system 350 (as discussed related to FIG. 2). The magazine cooling system 350 is, in some examples, includes a fluid coolant that flows through one or more coolant passageways 355. The magazine cooling system 350, including the one or more coolant passageways 355, is in communication with the inner wall 313a as a magazine heat conductive interface.

The electronics capsule 320 is brought into contact (e.g., engaged) with the inner wall 313a of magazine body 310 using an interface shoring 360. The interface shoring 360 illustrated in FIG. 3A or 3B is similar to the interface shoring 260, as discussed related to FIG. 2. The interface shoring 360 is, for example, positioned, supported, or the like on an interface shoring bearing surface 362. The interface bearing surface 362 is an example of a shelf that separates one capsule socket from another capsule socket. The interface shoring 360, for example, drives the inner wall 313a, as the magazine heat conductive interface, into engagement or contact with the capsule heat conductive interface 326. In an example, when the inner wall 313a, as the magazine heat conductive interface, and the capsule heat conductive interface 326 are in contact, these surfaces are in heat conductive engagement, as illustrated in FIG. 4.

The interface shoring 360, for example, biases or applies a force against a lower surface 328 of the electronics capsule 320. The biasing force or other force, such as a frictional force, applied against the lower surface 328 drives the electronics capsule 320 into, for example intimate engagement within a capsule socket 312.

In examples with the capsule heat conductive interface 326 and the inner wall 313a, as the magazine heat conductive interface, in heat conductive engagement, the contact between the capsule heat conductive interface 326 and the inner wall 313a is increased, as compared to contact without the interface shoring 360. With an increased contact between the capsule heat conductive interface 326 and the inner wall 313a, as the magazine heat conductive interface, the temperature of the electronics capsule 320, in some examples, is reduced as compared to examples without independent capsule cooling system 330 and magazine cooling system 350.

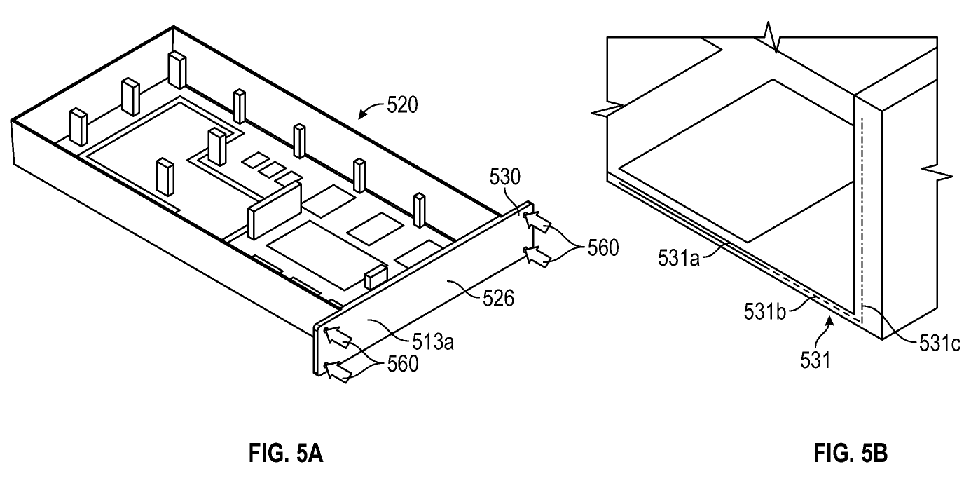

Illustrated in FIGS. 5A and 5B illustrate another example of a capsule cooling system 530. The capsule cooling system 530 is, for example positioned on or proximate to a front face 513a of an electronics capsule 520. In an example, the capsule cooling system 530 includes a heat pipe 531. The heat pipe 531 is similar to the heat pipe 331, as discussed relative to FIG. 4. The heat pipe 531 extends, for example around the perimeter of the electronics capsule 520 and includes a cooling section 531c positioned, for example, proximate to, or within the walls of the electronics capsule 520. In an example, the adiabatic section 531b, or the section where the fluid changes to vapor, is positioned between the cooling section 531c and the heat receiving section 531a that receives heat from the system.

An example of a heat pipe 531 is an oscillating heat pipe. The heat pipe 331 as an oscillation heat pipe is, for example positioned proximate to a capsule heat conductive interface 526. In an example the capsule heat conductive interface 526 is the front face 513a or front surface of the electronics capsule 520.

The capsule heat conductive interface 526 is in communication with the magazine body 110, 210, 310 (as illustrated in FIGS. 1, 2 or 4). The capsule heat conductive interface 526 is optionally in communication with the magazine body 110, 210, 310 to be in contact with the magazine cooling system 150, 350 (as illustrated related to FIGS. 1 or FIG. 4). The capsule heat conductive interface 526, in some examples, is fastened to the magazine body 110, 210, 310 with an interface shoring 560. The shoring 560 is, for example, a fastener or biasing member that drives or brings the capsule heat conductive interface 526 into contact, such as an intimate contact, with the magazine body 110, 210, 310. In an example, the capsule heat conductive interface 526 transfers the heat towards the shoring 560.

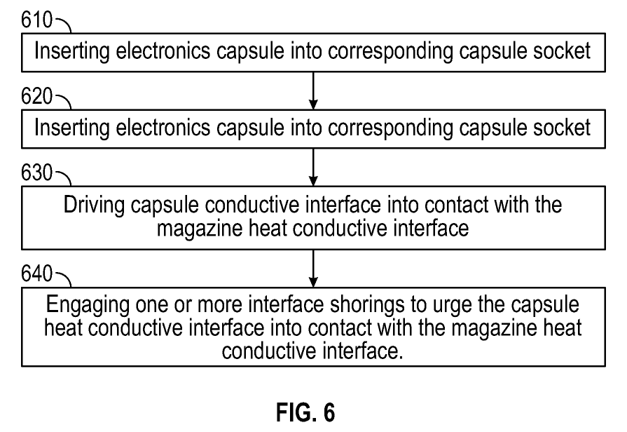

Illustrated in FIG. 6 is an example, a method of cooling an electronics system includes bringing one or more of the electronic capsules into contact, such as intimate contact with a cooling system positioned relative to, or with an electronics magazine. For example, the one or more electronics capsules is inserted into a corresponding capsule socket of an electronics magazine, 610. The one or more electronics capsule includes an electronics unit housed within a capsule housing and a capsule cooling system. The capsule cooling system includes a capsule heat conductive interface.

The one or more electronic capsules is positioned in in the corresponding capsule socket, 620. The corresponding capsule socket includes a magazine heat conductive interface. The magazine heat conductive interface is, for example, in communication with a magazine cooling system. The magazine cooling system is optionally a heat sink.

The capsule heat conductive interface is then urged, driven or biased into contact with the magazine heat conductive interface, 630. For example, the capsule heat conductive interface is associated with an independent cooling system from the cooling system associated with the magazine cooling system.

The one or more interface shorings is, for example, engaged to urge the capsule heat conductive interface into contact with the magazine heat conductive interface, 640. When the capsule heat conductive interface is in contact, such as in intimate contact, with the magazine heat conductive interface, the heat from the electronics capsule is, for example more efficiently removed.

### Aspects

Aspect 1 can include subject matter such as an electronics cooling assembly comprising: an electronics magazine including: a magazine body; one or more capsule sockets; a magazine cooling system enveloping the one or more capsule sockets; and a magazine heat conductive interface associated with each of the one or more capsule sockets; one or more electronics capsules, each of the one or more electronics capsules includes: a capsule body configured for reception within at least one of the one or more capsule sockets; an electronics unit within the capsule body; a capsule cooling system isolated from the magazine cooling system; and a capsule heat conductive interface in communication with the electronics unit; and one or more interface shoring coupled with one or more of the electronics magazine or the one or more electronics capsules; wherein the one or more interface shoring are configured to drive the magazine heat conductive interface and capsule heat conductive interface into intimate heat conductive engagement with the capsule body received within the at least one capsule socket of the one or more capsule sockets.

Aspect 2 can include, or can optionally be combined with the subject matter of Aspect 1, to optionally include one or more capsule sockets is configured to support the one or more electronics capsules.

Aspect 3 can include, or can optionally be combined with the subject matter of one or any combination of Aspects 1 or 2 to optionally include the capsule cooling system includes a heat pipe.

Aspect 4 can include, or can optionally be combined with the subject matter of one or any combination of Aspects 1 to 3 to optionally include the capsule cooling system includes an oscillating heat pipe.

Aspect 5 can include, or can optionally be combined with the subject matter of one or any combination of Aspects 1 to 4 to optionally include the capsule cooling system is positioned relative to the capsule heat conductive interface.

Aspect 6 can include, or can optionally be combined with the subject matter of one or any combination of Aspects 1 to 5 to optionally include the one or more interface shorings are a wedgelock; wherein the wedgelock is configured to urge the magazine heat conductive interface into communication with the capsule heat conductive interface.

Aspect 7 can include, or can optionally be combined with the subject matter of one or any combination of Aspects 1 to 6 to optionally include The electronics cooling assembly of clause 1, wherein the electronics magazine includes one or more accommodating walls; wherein the magazine cooling system is housed within the one or more accommodating walls.

Aspect 8 can include, or can optionally be combined with the subject matter of one or any combination of Aspects 1 to 7 to optionally include the electronics capsule includes one or more tapered surfaces; wherein the one or more tapered surfaces includes the capsule heat conductive interface.

Aspect 9 can include, or can optionally be combined with the subject matter of one or any combination of Aspects 1 to 8 to optionally include the magazine heat conductive interface is reciprocally formed to interface with the one or more tapered surfaces.

Aspect 10 can include subject matter such as an electronics cooling system comprising: an electronics magazine including: a magazine body; one or more capsule sockets; one or more interface shorings positioned within the magazine body relative to the one or more capsule sockets; and a magazine heat conductive interface positioned within the magazine body relative to at least one of the one or more capsule sockets; and one or more electronics capsules having a capsule housing, the one or more electronics capsules including: an electronics unit within the capsule housing; and a capsule cooling system including: a capsule heat conductive interface in communication with the electronics unit; wherein the one or more electronics capsules has an engaged configuration, the engaged configuration including: the one or more interface shorings configured to position the one or more electronics capsules in contact with the magazine body; and the one or more interface shorings configured to urge the capsule heat conductive interface into contact with the magazine heat conductive interface.

Aspect 11 can include, or can optionally be combined with the subject matter of one or any combination of Aspects 10 to optionally include the capsule cooling system includes an oscillating heat pipe.

Aspect 12 can include, or can optionally be combined with the subject matter of one or any combination of Aspects 10 or 11 to optionally include The electronics cooling system of clause 10, wherein the capsule heat conductive interface includes a tapered surface and the magazine heat conductive interface includes a complementary tapered surface.

Aspect 13 can include, or can optionally be combined with the subject matter of one or any combination of Aspects 10 to 12 to optionally include the electronics cooling system of clause 10, wherein the magazine includes a magazine cooling system extending within the magazine body; wherein the capsule cooling system and the magazine cooling system are configured to cooperatively remove heat from the electronics cooling system.

Aspect 14 can include or can optionally be combined with the subject matter of one or any combination of Aspects 10 to 13 to optionally include the electronics cooling system of clause 10, wherein the one or more interface shorings are configured to position the one or more capsule heat conductive interface in intimate contact with the magazine heat conductive interface.

Aspect 15 can include, or can optionally be combined with the subject matter of one or any combination of Aspects 10 to 14 to optionally include the electronics cooling system of clause 10, wherein the electronics capsule includes: a liquid condenser area positioned on the electronics capsule body.

Aspect 16 can include, or can optionally be combined with the subject matter of one or any combination of Aspects 10 to 15 to optionally include the magazine cooling system includes a cooling inlet and a cooling outlet; wherein in the engaged configuration, the magazine cooling system at least partially envelopes the electronics capsule.

Aspect 17 can include, or can optionally be combined with the subject matter of one or any combination of Aspects 10 to 16 to optionally include the one or more interface shorings are a wedgelock.

Aspect 18 can include, or can optionally be combined with the subject matter of one or any combination of Aspects 10 to 17 to optionally include the magazine body includes one or more magazine shelves, each shelf configured to support one electronics capsule; wherein one or more electronics capsules are stacked within the magazine body.

Aspect 19 can include, or can optionally be combined with the subject matter of one or any combination of Aspects 10 to 18 to optionally include the electronics unit includes one or more of a radar module, server module, avionic module, or control module

Aspect 20 can include subject matter such as a method of cooling an electronics system comprising: inserting one or more electronics capsules into a corresponding capsule socket of an electronics magazine; wherein the one or more electronics capsule includes an electronics unit housed within a capsule housing and a capsule cooling system; wherein the capsule cooling system includes a capsule heat conductive interface; positioning the one or more electronic capsules in the corresponding capsule socket; wherein the corresponding capsule socket includes a magazine heat conductive interface; urging the capsule heat conductive interface into contact with the magazine heat conductive interface; and engaging one or more interface shorings is to urge the capsule heat conductive interface into contact with the magazine heat conductive interface.

The above description includes references to the accompanying drawings, which form a part of the detailed description. The drawings show, by way of illustration, specific embodiments in which the invention can be practiced. These embodiments are also referred to herein as “aspects” or “examples.” Such aspects or example can include elements in addition to those shown or described. However, the present inventors also contemplate aspects or examples in which only those elements shown or described are provided. Moreover, the present inventors also contemplate aspects or examples using any combination or permutation of those elements shown or described (or one or more features thereof), either with respect to a particular aspects or examples (or one or more features thereof), or with respect to other Aspects (or one or more features thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

The above description is intended to be illustrative, and not restrictive. For example, the above-described aspects or examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as aspects, examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. An electronics cooling assembly comprising:
an electronics magazine including:
a magazine body;
one or more capsule sockets;
a magazine cooling system enveloping the one or more capsule sockets; and
a magazine heat conductive interface associated with each of the one or more capsule sockets;
one or more electronics capsules, each of the one or more electronics capsules includes:
a capsule body configured for reception within at least one of the one or more capsule sockets;
an electronics unit within the capsule body;
a capsule cooling system isolated from the magazine cooling system; and
a capsule heat conductive interface in communication with the electronics unit; and
one or more interface shoring coupled with one or more of the electronics magazine or the one or more electronics capsules;
wherein the one or more interface shoring are configured to drive the magazine heat conductive interface and capsule heat conductive interface into intimate heat conductive engagement with the capsule body received within the at least one capsule socket of the one or more capsule sockets.

2. The electronics cooling assembly of claim 1, including:
one or more capsule sockets is configured to support the one or more electronics capsules.

3. The electronics cooling assembly of claim 1, wherein the capsule cooling system includes a heat pipe.

4. The electronics cooling assembly of claim 1, wherein the capsule cooling system includes an oscillating heat pipe.

5. The electronics cooling assembly of claim 1, wherein the capsule cooling system is positioned relative to the capsule heat conductive interface.

6. The electronics cooling assembly of claim 1, wherein the one or more interface shorings are a wedgelock;
wherein the wedgelock is configured to urge the magazine heat conductive interface into communication with the capsule heat conductive interface.

7. The electronics cooling assembly of claim 1, wherein the electronics magazine includes one or more accommodating walls;
wherein the magazine cooling system is housed within the one or more accommodating walls.

8. The electronics cooling assembly of claim 1, wherein the electronics capsule includes one or more tapered surfaces;
wherein the one or more tapered surfaces includes the capsule heat conductive interface.

9. The electronics cooling assembly of claim 8, wherein the magazine heat conductive interface is reciprocally formed to interface with the one or more tapered surfaces.

10. An electronics cooling system comprising:
an electronics magazine including:
a magazine body;
one or more capsule sockets;
one or more interface shorings positioned within the magazine body relative to the one or more capsule sockets; and
a magazine heat conductive interface positioned within the magazine body relative to at least one of the one or more capsule sockets; and
one or more electronics capsules having a capsule housing, the one or more electronics capsules including:
an electronics unit within the capsule housing; and
a capsule cooling system including:
a capsule heat conductive interface in communication with the electronics unit;
wherein the one or more electronics capsules has an engaged configuration, the engaged configuration including:
the one or more interface shorings configured to position the one or more electronics capsules in contact with the magazine body; and
the one or more interface shorings configured to urge the capsule heat conductive interface into contact with the magazine heat conductive interface.

11. The electronics cooling system of claim 10, wherein the capsule cooling system includes an oscillating heat pipe.

12. The electronics cooling system of claim 10, wherein the capsule heat conductive interface includes a tapered surface and the magazine heat conductive interface includes a complementary tapered surface.

13. The electronics cooling system of claim 10, wherein the magazine includes a magazine cooling system extending within the magazine body;
wherein the capsule cooling system and the magazine cooling system are configured to cooperatively remove heat from the electronics cooling system.

14. The electronics cooling system of claim 10, wherein the one or more interface shorings are configured to position the one or more capsule heat conductive interface in intimate contact with the magazine heat conductive interface.

15. The electronics cooling system of claim 10, wherein the electronics capsule includes:
a liquid condenser area positioned on the electronics capsule body.

16. The electronics cooling system of claim 10, wherein the magazine cooling system includes a cooling inlet and a cooling outlet;
wherein in the engaged configuration, the magazine cooling system at least partially envelopes the electronics capsule.

17. The electronics cooling system of claim 10, wherein the one or more interface shorings are a wedgelock.

18. The electronics cooling system of claim 10, wherein the magazine body includes one or more magazine shelves, each shelf configured to support one electronics capsule;
wherein one or more electronics capsules are stacked within the magazine body.

19. The electronics cooling system of claim 10, wherein the electronics unit includes one or more of a radar module, server module, avionic module, or control module.

20. A method of cooling an electronics system comprising:
inserting one or more electronics capsules into a corresponding capsule socket of an electronics magazine;
wherein the one or more electronics capsule includes an electronics unit housed within a capsule housing and a capsule cooling system;
wherein the capsule cooling system includes a capsule heat conductive interface;
positioning the one or more electronic capsules in the corresponding capsule socket;
wherein the corresponding capsule socket includes a magazine heat conductive interface;
urging the capsule heat conductive interface into contact with the magazine heat conductive interface; and
engaging one or more interface shorings is to urge the capsule heat conductive interface into contact with the magazine heat conductive interface.
